(19) United States
(12) Patent Application Publication
(10) Pub. No.: US 2013/0075752 A1
(43) Pub. Date: Mar. 28, 2013

(54) SEMICONDUCTOR DEVICE AND METHOD OF MANUFACTURING THE SAME

(71) Applicant: Junji KOTANI, Isehara (JP)

(72) Inventor: Junji KOTANI, Isehara (JP)

(73) Assignee: FUJITSU LIMITED, Kawasaki-shi (JP)

(21) Appl. No.: 13/602,509

(22) Filed: Sep. 4, 2012

(30) Foreign Application Priority Data
Sep. 27, 2011 (JP) 2011-211562

(51) Int. Cl. H01L 29/778; H01L 21/335; H01L 29/205

(52) U.S. Cl. 257/76; 438/172; 257/E29.246; 257/E29.091; 257/E21.403

(57) ABSTRACT

A semiconductor device includes: a first semiconductor layer formed on a substrate; a second semiconductor layer formed on the first semiconductor layer; a third semiconductor layer formed on the second semiconductor layer; a gate electrode formed on the third semiconductor layer; and a source electrode and a drain electrode formed in contact with the second semiconductor layer, wherein a semiconductor material of the third semiconductor layer is doped with a p-type impurity element; and the third semiconductor layer has a jutting out region that juts out beyond an edge of the gate electrode toward a side where the drain electrode is provided.

### CROSS-REFERENCE TO RELATED APPLICATION(S)

This application is based upon and claims the benefit of priority of the prior Japanese Patent Application No. 2011-211562, filed on Sep. 27, 2011, the entire contents of which are incorporated herein by reference.

### FIELD

The embodiments discussed herein are related to semiconductor devices and their manufacturing methods.

### BACKGROUND

Nitride semiconductors like GaN, AlN, InN, etc., or materials that are mixed crystals of those nitride semiconductors have wide band gaps, and are used for high power electric devices, short wavelength light emitting devices, etc. Of those devices, as for the high power devices, technologies relating to field-effect transistors (FETs), or more specifically high electron mobility transistors (HEMTs) are being developed. Such nitride semiconductor based HEMTs are used for high power and high efficiency amplifiers, high power switching devices, etc.

For example, GaN, one kind of the nitride semiconductors, has a band gap of 3.4 eV, which is wider than a band gap of Si (1.1 eV) or a band gap of GaAs (1.4 eV), and has a high breakdown electric field intensity. In the GaN based HEMT, an AlGaN/GaN hetero-structure is formed, and GaN is used as an electron channel layer while AlGaN is used as an electron donor layer. This AlGaN/GaN hetero-structure induces piezoelectric polarization due to lattice distortions caused by a difference in the lattice constant between AlGaN and GaN, producing highly concentrated two dimensional electron gas (2DEG) in the GaN layer near the interface. Applications of such GaN based HEMTs are being studied particularly for high efficiency switching elements, high withstand voltage power elements for electric vehicles, etc.

It is strongly desirable that such high withstand voltage power elements have a normally-off feature in view of circuit designing or the like. However, it is difficult for the HEMT having the AlGaN/GaN hetero-structure to be normally-off since the highly concentrated 2DEG is produced due to a polarization difference. As a method of making the HEMT having the AlGaN/GaN hetero-structure to be normally-off without increasing an ON-resistance, a structure in which a p-GaN layer is layered directly below a gate electrode is disclosed. According to such a structure, holes may be injected from the p-GaN layer directly below the gate electrode, making it possible to reduce an electron concentration of the 2DEG in the electron channel layer. Accordingly, a threshold voltage may be shifted to a positive side, allowing the HEMT to be normally-off without increasing the ON-resistance.
[Patent Document] Japanese Laid-open Patent Publication No. 2002-359256
[Patent Document] Japanese Laid-open Patent Publication No. 2008-98434

An example of a conventional HEMT having a p-GaN layer will now be described in detail with reference to FIGS. 1A and 1B. In the HEMT having this structure, a buffer layer 912, an electron channel layer 913, and an electron donor layer 914 are formed on a substrate 911 of Si or the like. Furthermore, a p-GaN layer 915 is formed on the electron donor layer 914 at a region where a gate electrode 921 is to be formed. The gate electrode 921 is formed on the p-GaN layer 915.

A source electrode 922 and a drain electrode 923 are formed on the electron donor layer 914. In the HEMT having this structure, 2DEG 913a is produced in the electron channel layer 913 near an interface of i-GaN that forms the electron channel layer 913 and i-AlGaN that forms the electron donor layer 914. However, the formation of the p-GaN layer 915 may be able to deplete electrons from part of the 2DEG 913a directly below the gate electrode 921, making it possible to be normally-off.

Note that, in the HEMT having such a structure, the p-GaN layer 915 is typically formed in a shape substantially the same as that of the gate electrode 921 since it is desirable to deplete electrons from the part of the 2DEG 913a directly below the gate electrode 921.

When an electric voltage is applied between the source and the drain of the HEMT in which the p-GaN layer 915 is formed as illustrated in FIG. 1A, an electric filed is generated as illustrated in FIG. 1B. More specifically, the electric field peaks at a side of the gate electrode 921, which is closer to the drain electrode 923, thereby creating a state in which the electric field is being converge at that position. When the electric field converges as described above, the total withstand voltage of HEMT decreases. This may lower the reliability of HEMT and even cause a breakdown of HEMT due to the voltage applied between the source and the drain.

### SUMMARY

According to an aspect of the embodiments, a semiconductor device includes: a first semiconductor layer formed on a substrate; a second semiconductor layer formed on the first semiconductor layer; a third semiconductor layer formed on the second semiconductor layer; a gate electrode formed on the third semiconductor layer; and a source electrode and a drain electrode formed in contact with the second semiconductor layer, wherein a semiconductor material of the third semiconductor layer is doped with a p-type impurity element; and the third semiconductor layer has a jutting out region that juts out beyond an edge of the gate electrode toward a side where the drain electrode is provided.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1A is a structure diagram of a conventional GaN based HEMT, and

FIG. 1B is a diagram illustrating electric field intensity thereof;

FIG. 2A is an explanatory diagram of a semiconductor device according to a first embodiment, and FIG. 2B is a diagram illustrating electric field intensity thereof;

FIGS. 3A-3C are process diagrams (1) for a manufacturing method of the semiconductor device according to the first embodiment;

FIGS. 4A and 4B are process diagrams (2) for the manufacturing method of the semiconductor device according to the first embodiment;

FIG. 5 is a characteristic diagram of a drain voltage and a drain current in the semiconductor device according to the first embodiment;

FIG. 6 is a structure diagram of a semiconductor device according to a second embodiment;

FIGS. 7A-7C are process diagrams (1) for a manufacturing method of the semiconductor device according to the second embodiment;

FIGS. 8A-8C are process diagrams (2) for the manufacturing method of the semiconductor device according to the second embodiment;

FIG. 9 is a process diagram (3) for the manufacturing method of the semiconductor device according to the second embodiment;

FIG. 10 is a characteristic diagram of a jutting out region's thickness and the drain voltage in the semiconductor device according to the second embodiment;

FIG. 11 is a structure diagram of a semiconductor device according to a third embodiment;

FIGS. 12A-12C are process diagrams (1) for a manufacturing method of the semiconductor device according to the third embodiment;

FIGS. 13A-13C are process diagrams (2) for the manufacturing method of the semiconductor device according to the third embodiment;

FIG. 14 is a process diagram (3) for the manufacturing method of the semiconductor device according to the third embodiment;

FIG. 15 is a structure diagram of a semiconductor device according to a fourth embodiment;

FIGS. 16A-16C are process diagrams (1) for a manufacturing method of the semiconductor device according to the fourth embodiment;

FIGS. 17A-17C are process diagrams (2) for the manufacturing method of the semiconductor device according to the fourth embodiment;

FIG. 18 is an explanatory diagram of a discrete packaged semiconductor device according to a fifth embodiment;

FIG. 19 is a circuit diagram of a power supply apparatus according to the fifth embodiment; and

FIG. 20 is a structure diagram of a high power amplifier according to the fifth embodiment.

### DESCRIPTION OF EMBODIMENTS

Hereinafter, embodiments will be described. Note that like reference numerals denote like elements, and the descriptions thereof are omitted.

### First Embodiment

Semiconductor Device

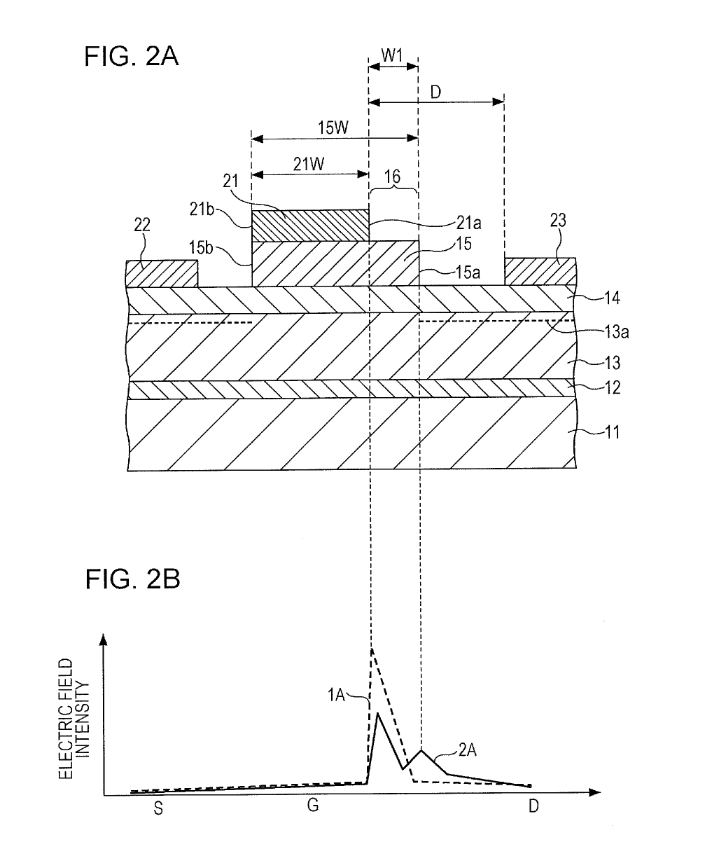

A semiconductor device according to the first embodiment is described with reference to FIGS. 2A and 2B. As illustrated in FIG. 2A, in the semiconductor device of the present embodiment, a buffer layer 12, an electron channel layer 13 that serves as a first semiconductor layer, and an electron donor layer 14 that serves as a second semiconductor layer are sequentially formed on a substrate 11. On a predetermined region of the electron donor layer 14, a p-GaN layer 15 that serves as a third semiconductor layer is formed, and on the p-GaN layer 15 thus formed, a gate electrode 21 is formed. Furthermore, a source electrode 22 and a drain electrode 23 are formed on the electron donor layer 14. In the present embodiment, the p-GaN layer 15 uses GaN that is doped with Mg, which is an impurity element that makes p-type. Thus, in the present embodiment, the p-GaN layer 15 may also be referred to as a p-type doped layer. Furthermore, the third semiconductor layer may be any layer as long as it is formed of a p-type nitride semiconductor.

In the present embodiment, the p-GaN layer 15 and the gate electrode 21 are formed in such a way that, on a side toward the drain electrode 23, an edge 15a of the p-GaN layer 15 is positioned closer to the drain electrode 23 than an edge 21a of the gate electrode 21. In the description of the present embodiment, it is assumed that an edge 15b of the p-GaN layer 15 and an edge 21b of the gate electrode 21 are aligned with each other on a side toward the source electrode 22. Alternatively, the edge 15b and the edge 21b are not aligned with each other.

Accordingly, a width 15W of the p-GaN layer 15 in a direction from the source electrode 22 to the drain electrode 23 is formed such that the width 15W is larger than a width 21W of the gate electrode 21 in the direction from the source electrode 22 to the drain electrode 23. Thus, in the p-GaN layer 15, a jutting out region 16 that juts out beyond the gate electrode 21 toward the drain electrode 23 is formed. A width W1 of the jutting out region 16 in the direction toward the drain electrode 23 is 15W-21W when the edge 15b of the p-GaN layer 15 and the edge 21b of the gate electrode 21 are aligned with each other.

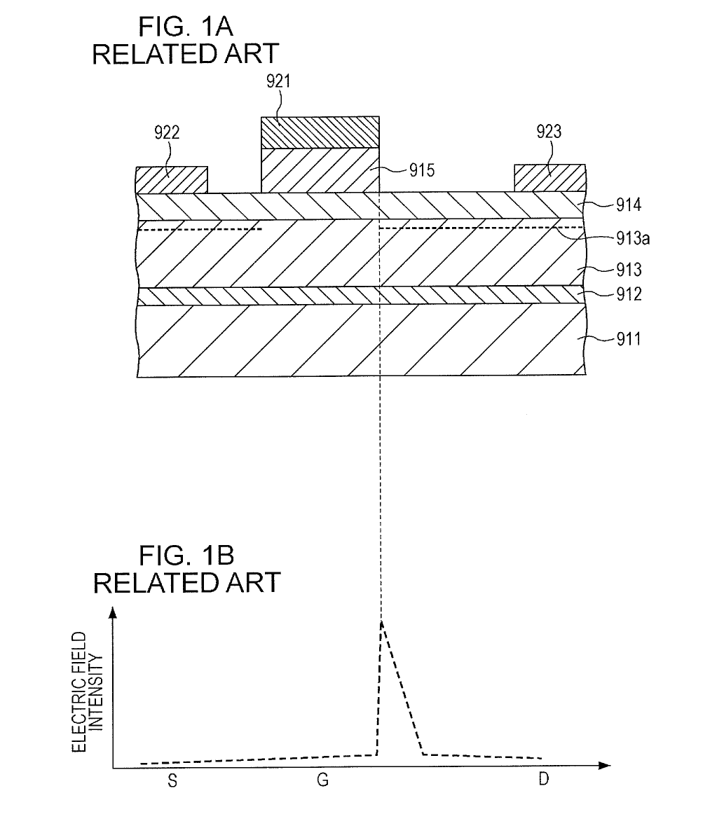

A structure of the semiconductor device according to the present embodiment as described above produces an electric field distribution such as illustrated by a solid line 2A in FIG. 2B. Note that a dash line 1A is the one illustrated in FIG. 1B, and produced by the structure illustrated in FIG. 1A. In the semiconductor device according to the present embodiment, as illustrated by the solid line 2A, the electric field converges at two places, one near the edge 21a of the gate electrode 21 and the other near the edge 15a of the p-GaN layer 15. Accordingly, peaks of the electric field intensity may be reduced at the places where the electric field converges. It is inferred that the reason why the electric field converges at the two places as described above is that the electron population in 2DEG 13a is reduced at regions directly below the gate electrode 21 as well as the p-GaN layer 15, thereby causing spreading in the electric field, as described below. Accordingly, the peaks of the electric field intensity may be reduced, and a total withstand voltage of the semiconductor device may be increased, by forming the edge 15a of the p-GaN layer 15 closer to the drain electrode 23 than the edge 21a of the gate electrode 21 on the side toward the drain electrode 23.

Thus, in the present embodiment, the 2DEG 13a with an electron depleted region, which is positioned directly below the p-GaN layer 15, is formed in the electron channel layer 13 near an interface of the electron channel layer 13 and the electron donor layer 14.

When the edge 15a of the p-GaN layer 15 is formed too close to the drain electrode 23 compared to the edge 21a of the gate electrode 21, the electron depleted region expands in the 2DEG 13a. Such an arrangement is not preferable since it increases the ON-resistance. Accordingly, it is preferable that the width W1 of the jutting out region 16 satisfies W1≦0.8×D, or more preferably W1≦0.5×D, where D is a distance between the gate electrode 21 and the drain electrode 23.

When 0<W1, effects of the present embodiment may be obtained. However, the electric field convergence is not relaxed when the edge 15a of the p-GaN layer 15 and the edge 21a of the gate electrode 21 are too close to each other. Accordingly, it is preferable that the width W1 of the jutting out region 16 satisfies 100 nm≦W1, or more preferably 200 nm≦W1.

Semiconductor Device Manufacturing Method

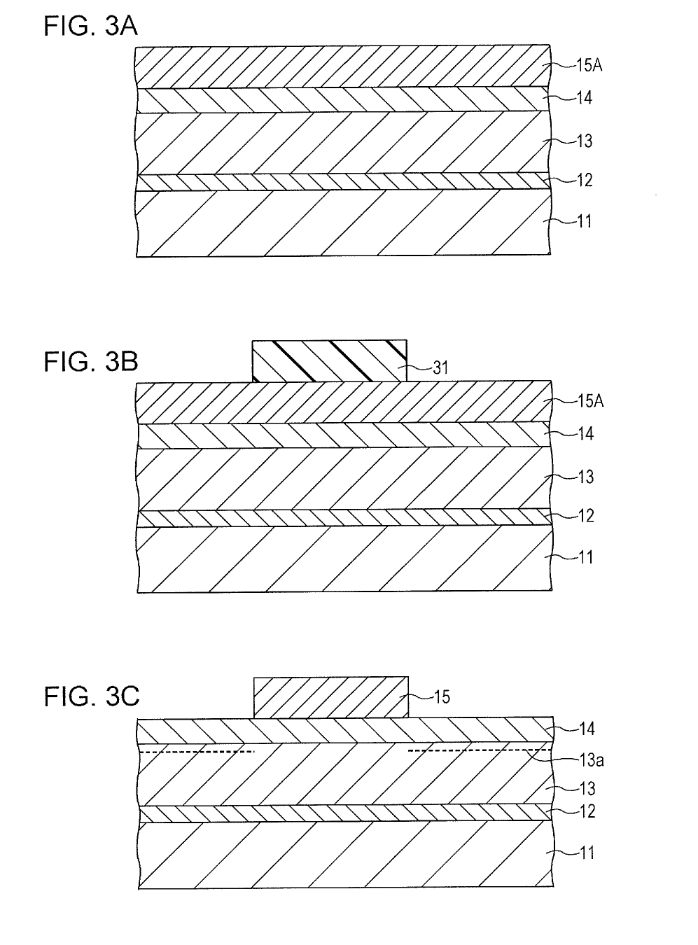

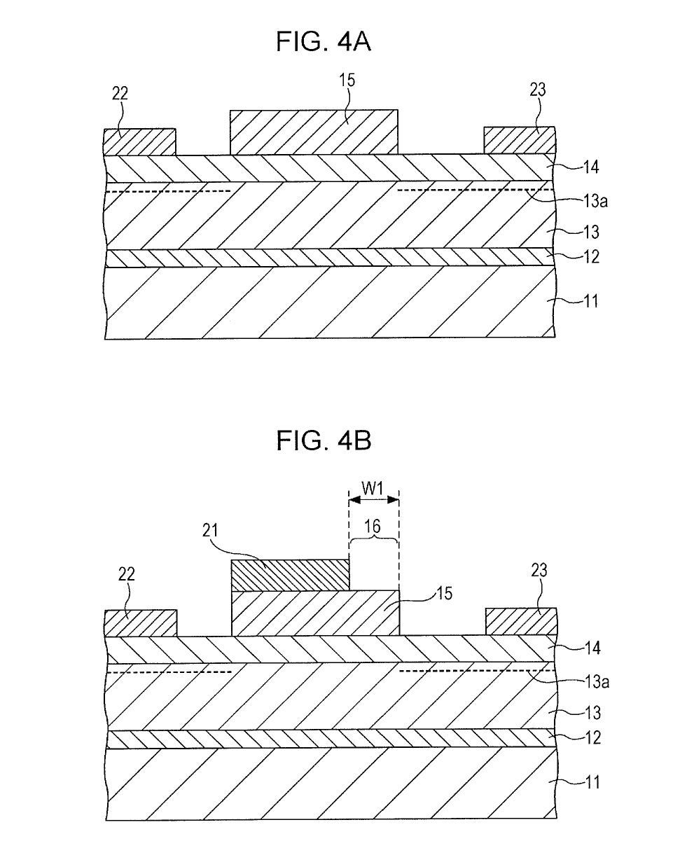

Next, a method of manufacturing the semiconductor device according to the first embodiment is described with reference to FIGS. 3A-3C and 4A-4B.

First, as illustrated in FIG. 3A, nitride semiconductor layers of the buffer layer 12, the electron channel layer 13, the electron donor layer 14, and a p-GaN film 15A, from which the p-GaN layer 15 is to be formed, are formed on the substrate 11 by epitaxially growing the respective layers by a MOVPE method. In the present embodiment, the buffer layer 12 may be formed, for example, by first forming about 160 nm thickness of AlN buffer layer and then forming about 500 nm thickness of AlGaN buffer layer on the AlN buffer layer thus formed. The electron channel layer 13 that serves as the first semiconductor layer is formed of about 1 μm thickness of GaN. The electron donor layer 14 that serves as the second semiconductor layer is formed of about 20 nm thickness of AlGaN. The p-GaN film 15A, from which the p-GaN layer 15 that serves as the third semiconductor layer is formed, is formed so as to have about 100 nm thickness, and is doped with Mg as an impurity element. The p-GaN film 15A may further include In, Al, etc.

When forming films of those nitride semiconductor layers by the MOVPE, TMA (trimethylaluminium) is used as a source gas for Al, TMG (trimethylgallium) is used as a source gas for Ga, and NH₃ (ammonia) is used as a source gas for N. Furthermore, Cp₂Mg (bis(cyclopentadienyl)magnesium) is used as a source gas for Mg. Those source gases are supplied together with a hydrogen (H₂) carrier gas to a reaction chamber of a MOVPE apparatus.

When the nitride semiconductor layers are being formed, the ammonia gas is supplied at a flow rate of 100-10000 sccm. Furthermore, when the nitride semiconductor layered are being formed, a growth pressure is 50-300 Torr and a growth temperature is 1000-1200° C. Instead of the MOVPE, the semiconductor layers described above may be alternatively formed by a molecular beam epitaxy (MBE) deposition.

For the substrate 11, a sapphire substrate, a Si substrate, or a SiC substrate may be used, for example. In the present embodiment, a Si (111) substrate is used as the substrate 11.

The AlGaN buffer in the buffer layer 12 is formed in such a way that, when the AlGaN buffer is expressed as AlₓGa₁₋ₓN, the value of X satisfies 0.2<x<0.8.

When the electron donor layer 14 is expressed as AlₓGa₁₋ₓN, the electron donor layer 14 is formed such that X has a value of 0.1-0.3. In the present embodiment, the electron donor layer 14 is formed such that the value of X is 0.2 or Al_{0.2}Ga_{0.8}N. The electron donor layer 14 may be i-AlGaN or n-AlGaN. When the n-AlGaN is being formed, Si is doped as the impurity element such that the Si concentration is 1×10¹⁸-1×10²⁰ cm⁻³, or for example, 1×10¹⁹ cm⁻³. In such a case, SiH₄ or the like may be used as the Si source gas, for example.

The p-GaN film 15A, from which the p-GaN layer 15 is formed, is formed of GaN doped with Mg as the impurity element such that the impurity concentration is 5×10¹⁸-5×10²⁰ cm⁻³. In the present embodiment, the p-GaN film 15A is doped with Mg such that the impurity concentration becomes 1×10¹⁹ cm⁻³. The p-GaN film 15 at right after the deposition includes hydrogen atoms within the film, and such hydrogen atoms are combined with Mg. Thus, Mg is not activated, and the film is still highly resistive. Therefore, a heat treatment or the like is performed in a nitrogen environment after the deposition to cause desorption of the hydrogen atoms from the film of the p-GaN film 15A so as to make the film p-type. In the semiconductor device of the present embodiment, the p-GaN film 15A is formed to have a film thickness within a range of 10-150 nm.

Next, as illustrated in FIG. 3B, a resist pattern 31 is formed on the p-GaN film 15A. Specifically, the resist pattern 31 is formed over a region where the p-GaN layer 15 is formed by coating photoresist over the p-GaN film 15A and then performing exposure and development processes using a photolithography apparatus.

Next, as illustrated in FIG. 3C, dry etching is performed using an reactive ion etching (RIE) or the like to remove the p-GaN film 15A from an exposed area where no resist pattern 31 is formed, thereby forming the p-GaN layer 15. In this way, the p-GaN layer 15 may be formed over the predetermined area of the electron donor layer 14. In the dry etching by the RIE or the like, a chlorine gas such as Cl₂, BCl₃, etc. may be used as an etching gas. After that, the resist pattern 31 is removed by organic solvent or the like.

Next, as illustrated in FIG. 4A, the source electrode 22 and the drain electrode 23 are formed on the electron donor layer 14. Specifically, a resist pattern (not indicated in the figure) is formed by coating photoresist over the electron donor layer 14 and then performing exposure and development processes using the photolithography apparatus. The resist pattern has openings over regions where the source electrode 22 and the drain electrode 23 are to be formed. Subsequently, a Ti/Al multilayer metal film is deposited, and then dipped into organic solvent or the like to remove the Ti/Al multilayer metal film deposited on the resist pattern together with the resist pattern itself by a lift-off method. Thus, the source electrode 22 and the drain electrode 23 made of Ti/Al are formed. In the Ti/Al multilayer metal film, a thickness of Ti is about 30 nm, and a thickness of Al is about 300 nm. Subsequently, rapid thermal annealing (RTA) is performed at a temperature of about 600° C. to form ohmic contacts.

Next, as illustrated in FIG. 4B, the gate electrode 21 is formed on the p-GaN layer 15. The gate electrode 21 is formed such that the p-GaN layer 15 has the predetermined jutting out region 16. Specifically, a resist pattern (not indicated in the figure) is formed by coating photoresist over the p-GaN layer 15 and then performing exposure and development processes using the photolithography apparatus. The resist pattern has an opening over a region where the gate electrode 21 is to be formed. Subsequently, a Ni/Au multilayer metal film is deposited, and then dipped into organic solvent or the like to remove the Ni/Au multilayer metal film deposited on the resist pattern together with the resist pattern itself by the lift-off method. Thus, the gate electrode 21 made of Ni/Au is formed. In the Ni/Au multilayer metal film, a thickness of Ni is about 100 nm, and a thickness of Au is about 300 nm. In the semiconductor device according to the present embodiment formed as described above, the width W1 of the jutting out region 16 on the p-GaN layer 15 is about 2 μm.

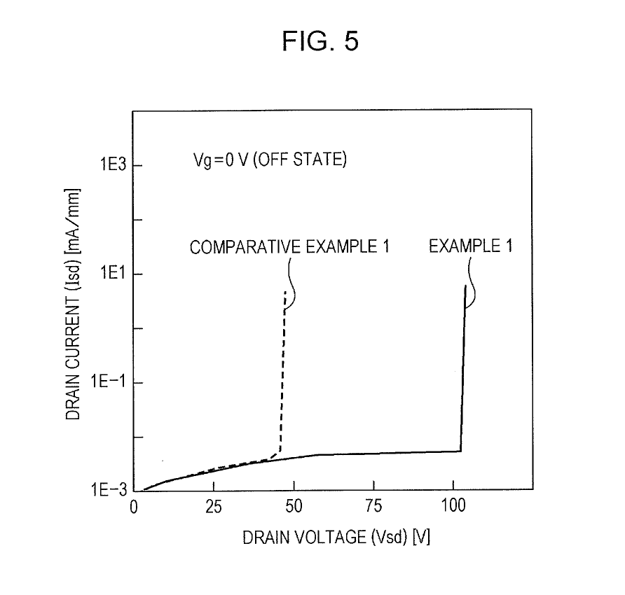

A relation between a drain voltage and a drain current in the semiconductor device according to the first embodiment is illustrated as an example 1 in FIG. 5. A comparative example 1 is a semiconductor device having the structure illustrated in FIG. 1, which is manufactured under substantially the same conditions as those of the example 1 except that no jutting out region is formed on the p-GaN layer 915 in the comparative example 1. As illustrated in FIG. 5, the withstand voltage of a semiconductor device according to the example 1 of the present embodiment is about 90 V or above while the withstand voltage of a semiconductor device according to the comparative example 1 is about 40 V. Accordingly, an insulating withstand voltage may be improved. A reason why the insulating withstand voltage of the semiconductor device according to the example 1 is improved as described above is that the electric field convergence is relaxed by having the jutting out region 16 on the p-GaN layer 15.

### Second Embodiment

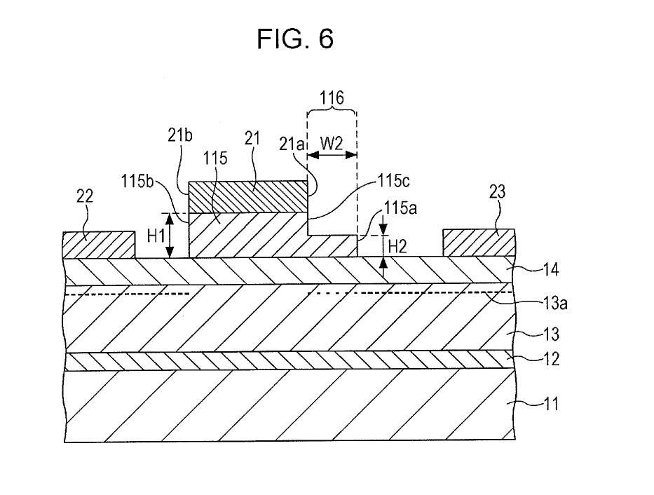

Next, a semiconductor device according to the second embodiment is described. As illustrated in FIG. 6, in the semiconductor device of the present embodiment, a buffer layer 12, an electron channel layer 13 that serves as a first semiconductor layer, and an electron donor layer 14 that serves as a second semiconductor layer are sequentially formed on a substrate 11. On a predetermined region of the electron donor layer 14, a p-GaN layer 115 that serves as a third semiconductor layer is formed, and a gate electrode 21 is formed on the p-GaN layer 115 thus formed. Furthermore, on the electron donor layer 14, a source electrode 22 and a drain electrode 23 are formed. In the present embodiment, the p-GaN layer 115 uses GaN doped with Mg, which is an impurity element that makes p-type.

The p-GaN layer 115 is formed in such a way that, on a side toward the drain electrode 23, an edge 115a of the p-GaN layer 115 juts out beyond an edge 21a of the gate electrode 21 toward the drain electrode 23, thereby forming a jutting out region 116. The jutting out region 116 is formed between the edge 115a and a portion 115c of the p-GaN layer 115, which is aligned with the edge 21a of the gate electrode 21 on the side toward the drain electrode 23. In the jutting out region 116, a width toward the drain electrode 23—namely a width from the portion 115c to the edge 115a of the p-GaN layer 115—will be referred to as W2. Furthermore, the jutting out region 116 of the p-GaN layer 115 is formed in such a way that a thickness thereof, —namely a thickness H2 of a region from the portion 115c to the edge 115a of the p-GaN layer 115—is less than a thickness H1 of the p-GaN layer 115 directly below the gate electrode 21. Furthermore, on a side toward the source electrode 22, an edge 115b of the p-GaN layer 115 and an edge 21b of the gate electrode 21 are aligned with each other.

In the semiconductor device according to the present embodiment, the thickness of the jutting out region 116 is made thinner. As a result, electrons are allowed to exist in 2DEG 13a at a region directly below the jutting out region 116, though the electron concentration is less than that of a region directly below an area where the p-GaN layer 115 is not formed. Accordingly, the ON-resistance increase may be alleviated further while the electric field convergence is being relaxed.

When the edge 115a of the p-GaN layer 115 is formed too close to the drain electrode 23 compared to the edge 21a of the gate electrode 21, the region having the less electron concentration expands within the 2DEG 13a. Thus, such an arrangement is not preferable since it increases the ON-resistance. Accordingly, it is preferable that the width W2 of the jutting out region 116 satisfies W2≦0.8×D, or more preferably W2≦0.5×D, where D is a distance between the gate electrode 21 and the drain electrode 23.

When 0<W2, effects of the present embodiment may be obtained. However, the electric field convergence is not relaxed when the edge 115a of the p-GaN layer 115 and the edge 21a of the gate electrode 21 are too close to each other. Accordingly, it is preferable that the width W2 of the jutting out region 116 satisfies 100 nm≦W2, or more preferably 200 nm≦W2.

Semiconductor Device Manufacturing Method

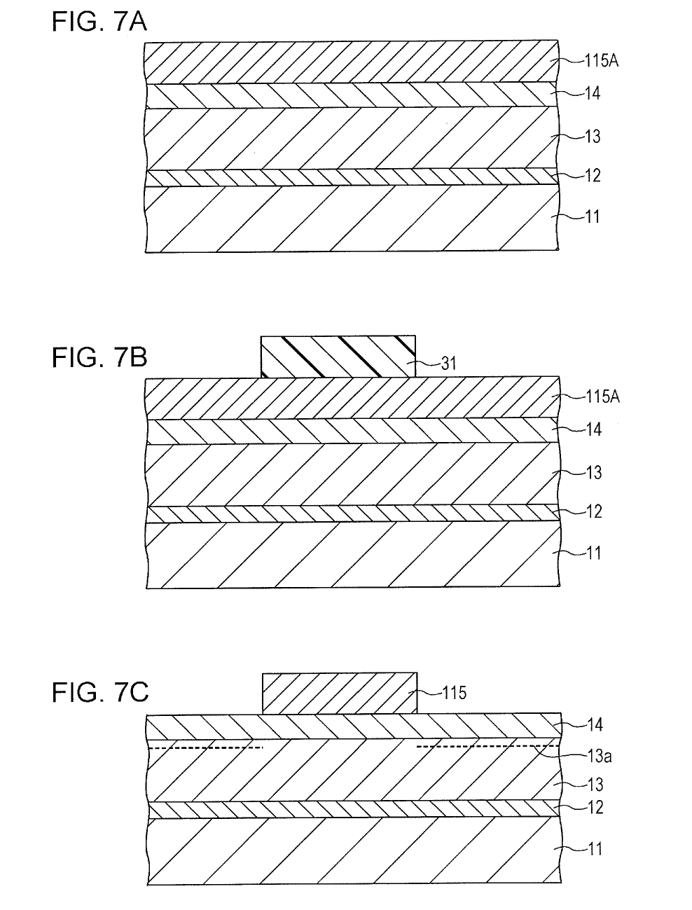

Next, a method of manufacturing the semiconductor device according to the second embodiment is described with reference to FIGS. 7A-7C, 8A-8C and 9.

First, as illustrated in FIG. 7A, nitride semiconductor layers of the buffer layer 12, the electron channel layer 13, the electron donor layer 14, and a p-GaN film 115A, from which the p-GaN layer 115 is to be formed, are formed on the substrate 11 by epitaxially growing the respective layers by a MOVPE method. In the present embodiment, the buffer layer 12 may be formed, for example, by first forming about 160 nm thickness of AlN buffer layer and then forming about 500 nm thickness of AlGaN buffer layer on the AlN buffer layer thus formed. The electron channel layer 13 that serves as the first semiconductor layer is formed of about 1 μm thickness of GaN. The electron donor layer 14 that serves as the second semiconductor layer is formed of about 20 nm thickness of AlGaN. The p-GaN film 115A, from which the p-GaN layer 115 that serves as the third semiconductor layer is formed, is formed so as to have about 100 nm thickness, and is doped with Mg as an impurity element. The p-GaN film 115A may further include In, Al, etc.

Next, as illustrated in FIG. 7B, a resist pattern 31 is formed on the p-GaN film 115A. Specifically, the resist pattern 31 is formed over a region where the p-GaN layer 115 is formed by coating photoresist over the p-GaN film 115A and then performing exposure and development processes using a photolithography apparatus.

Next, as illustrated in FIG. 7C, dry etching is performed using an RIE or the like to remove the p-GaN film 115A from an exposed area where no resist pattern 31 is formed, thereby forming the p-GaN layer 115. In the dry etching by the RIE or the like, a chlorine gas such as Cl₂, BCl₃, etc. may be used as an etching gas. After that, the resist pattern 31 is removed by organic solvent or the like.

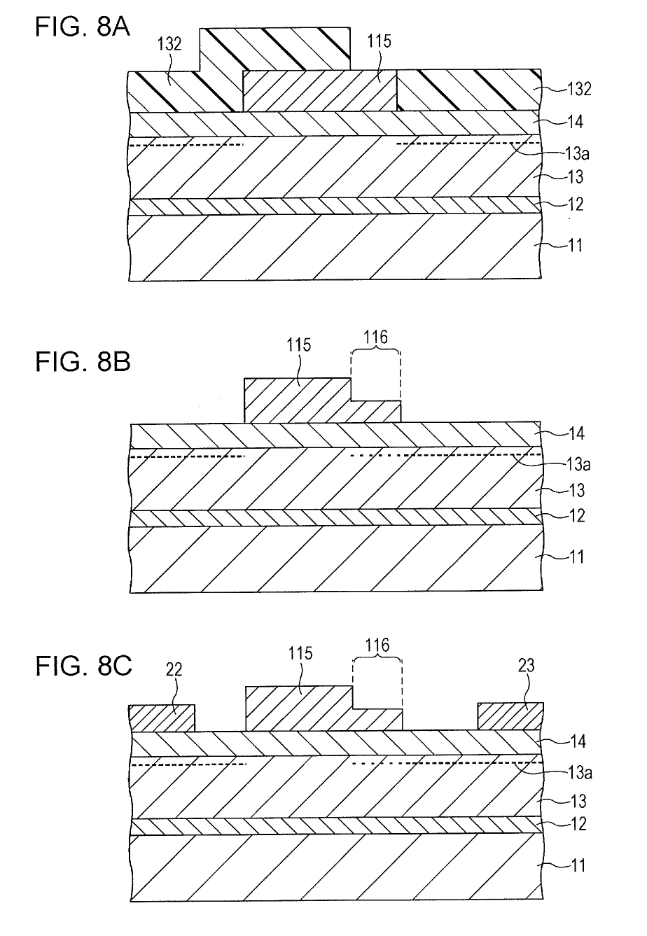

Next, as illustrated in FIG. 8A, a resist pattern 132 is formed on the p-GaN layer 115. The resist pattern 132 has an opening at a region where the jutting out region 116 is formed. Specifically, the resist pattern 132, which has the opening at the region where the jutting out region 116 is formed, is formed by coating photoresist over the p-GaN layer 115 and then performing exposure and development processes using the photolithography apparatus.

Next, as illustrated in FIG. 8B, dry etching is performed using an RIE or the like to remove part of the p-GaN layer 115 to make it thinner at an exposed area where no resist pattern 132 is formed, thereby forming the jutting out region 116. After that, the resist pattern 132 is removed by organic solvent or the like. Thus, the p-GaN layer 115 having the jutting out region 116 is formed on the predetermined area of the electron donor layer 14.

Next, as illustrated in FIG. 8C, the source electrode 22 and the drain electrode 23 are formed on the electron donor layer 14. Specifically, a resist pattern (not indicated in the figure) is formed by coating photoresist over the electron donor layer 14 and then performing exposure and development using the photolithography apparatus. The resist pattern has openings over regions where the source electrode 22 and the drain electrode 23 are to be formed. Subsequently, a Ti/Al multilayer metal film is deposited, and then dipped into organic solvent or the like to remove the Ti/Al multilayer metal film deposited on the resist pattern as well as the resist pattern by a lift-off method. Thus, the source electrode 22 and the drain electrode 23 made of Ti/Al are formed. In the Ti/Al multilayer metal film, a thickness of Ti is about 30 nm, and a thickness of Al is about 300 nm. Subsequently, rapid thermal annealing is performed at a temperature of about 600° C. to form ohmic contacts.

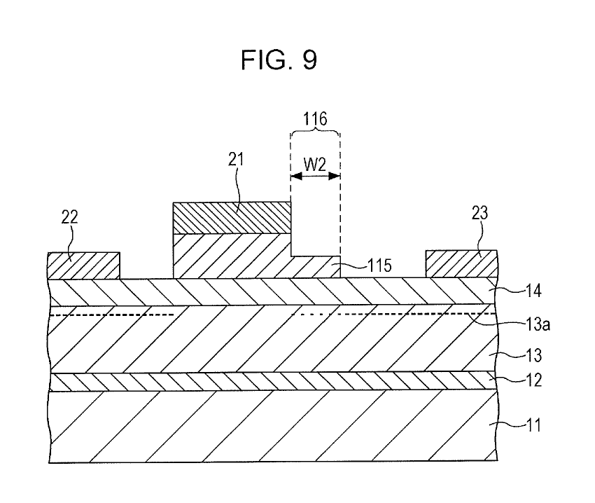

Next, as illustrated in FIG. 9, the gate electrode 21 is formed on the p-GaN layer 115 at a region except a region on which the jutting out region 116 is being formed. Specifically, a resist pattern (not indicated in the figure) is formed by coating photoresist over the p-GaN layer 115 and then performing exposure and development processes using the photolithography apparatus. The resist pattern has an opening over a region where the gate electrode 21 is to be formed. Subsequently, a Ni/Au multilayer metal film is deposited, and then dipped into organic solvent or the like to remove the Ni/Au multilayer metal film deposited on the resist pattern together with the resist pattern itself by the lift-off method. Thus, the gate electrode 21 made of Ni/Au is formed. In the Ni/Au multilayer metal film, a thickness of Ni is about 100 nm, and a thickness of Au is about 300 nm.

In the semiconductor device according to the present embodiment formed as described above, a region jutting out toward the drain electrode 23 beyond the edge of the gate electrode in the p-GaN layer 115—namely the jutting out region 116 of the p-GaN layer 115—has the width W2 of about 2 μm.

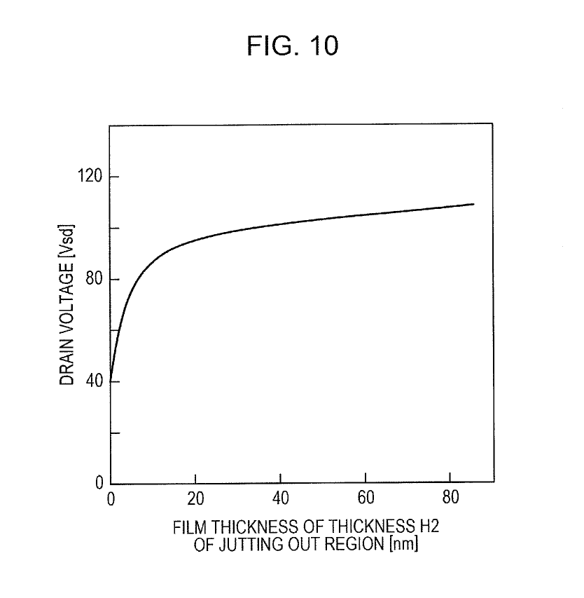

FIG. 10 illustrates a relation between the thickness H2 of the jutting out region 116 of the p-GaN layer 115 and a drain voltage Vsd that serves as the withstand voltage in the semiconductor device according to the present embodiment. As illustrated in FIG. 10, the drain voltage of about 100 V or more may be obtained by forming the jutting out region 116 in such a way that the thickness H2 is equal to 10 nm or more.

In the present embodiment, the jutting out region 116 of the p-GaN layer 115 may be formed in a stair-like shape. Specifically, the jutting out region 116 may be formed in a stair-like shape by repeating the step of forming a desired resist pattern illustrated in FIG. 8A and the step of dry etching illustrated in FIG. 8B.

Except for the matters described above, the contents of the present embodiment are similar to those of the first embodiment.

### Third Embodiment

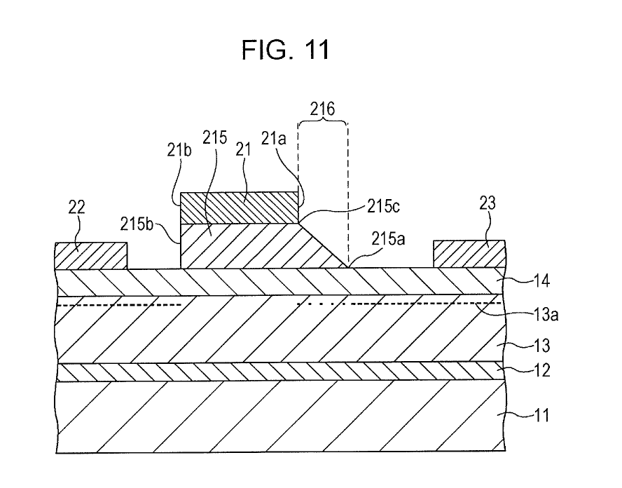

Next, a semiconductor device according to the third embodiment is described. As illustrated in FIG. 11, in the semiconductor device of the present embodiment, a buffer layer 12, an electron channel layer 13 that serves as a first semiconductor layer, and an electron donor layer 14 that serves as a second semiconductor layer are sequentially formed on a substrate 11. On a predetermined region of the electron donor layer 14, a p-GaN layer 215 that serves as a third semiconductor layer is formed, and a gate electrode 21 is formed on the p-GaN layer 215 thus formed. Furthermore, on the electron donor layer 14, a source electrode 22 and a drain electrode 23 are formed. In the present embodiment, the p-GaN layer 215 uses GaN doped with Mg, which is an impurity element that makes p-type.

The p-GaN layer 215 is formed in such a way that, on a side toward the drain electrode 23, an edge 215a of the p-GaN layer 215 juts out beyond an edge 21a of the gate electrode 21 toward the drain electrode 23, thereby forming a jutting out region 216. The jutting out region 216 is formed between the edge 215a and a portion 215c of the p-GaN layer 215, which is aligned with the edge 21a of the gate electrode 21 on the side toward the drain electrode 23. On a side toward the source electrode 22, an edge 215b of the p-GaN layer 215 and an edge 21b of the gate electrode 21 are aligned with each other. Furthermore, the jutting out region 216 is formed in such a way that a thickness thereof gradually decreases as a distance from the portion 215c increases toward the edge 215a—namely, as a distance from the side of the gate electrode 21 increases in a direction toward a position where the drain electrode 23 is provided.

By forming the jutting out region 216 with the gradual decreasing thickness as described above, electrons are allowed to distribute in 2DEG 13a directly below the jutting out region 216 in such a way that the electron concentration gradually decreases as a distance from a position directly below the edge 215a increases toward a position directly below the portion 215c. Accordingly, the ON-resistance increase may be alleviated while the electric field convergence is being relaxed furthermore. In the jutting out region 216, a width toward the drain electrode 23—namely a width from the portion 215c to the edge 215a of the p-GaN layer 215—will be referred to as W3.

When the edge 215a of the p-GaN layer 215 is formed too close to the drain electrode 23 compared to the edge 21a of the gate electrode 21, the electron depleted region expands within the 2DEG 13a. Such an arrangement is not preferable since it increases the ON-resistance. Accordingly, it is preferable that the width W3 of the jutting out region 216 satisfies W3≦0.8×D, or more preferably W3≦0.5×D, where D is a distance between the gate electrode 21 and the drain electrode 23.

When 0<W3, effects of the present embodiment may be obtained. However, the electric field convergence is not relaxed when the edge 215a of the p-GaN layer 215 and the edge 21a of the gate electrode 21 are too close to each other. Accordingly, it is preferable that the width W3 of the jutting out region 216 satisfies 100 nm≦W3, or more preferably 200 nm≦W3.

Semiconductor Device Manufacturing Method

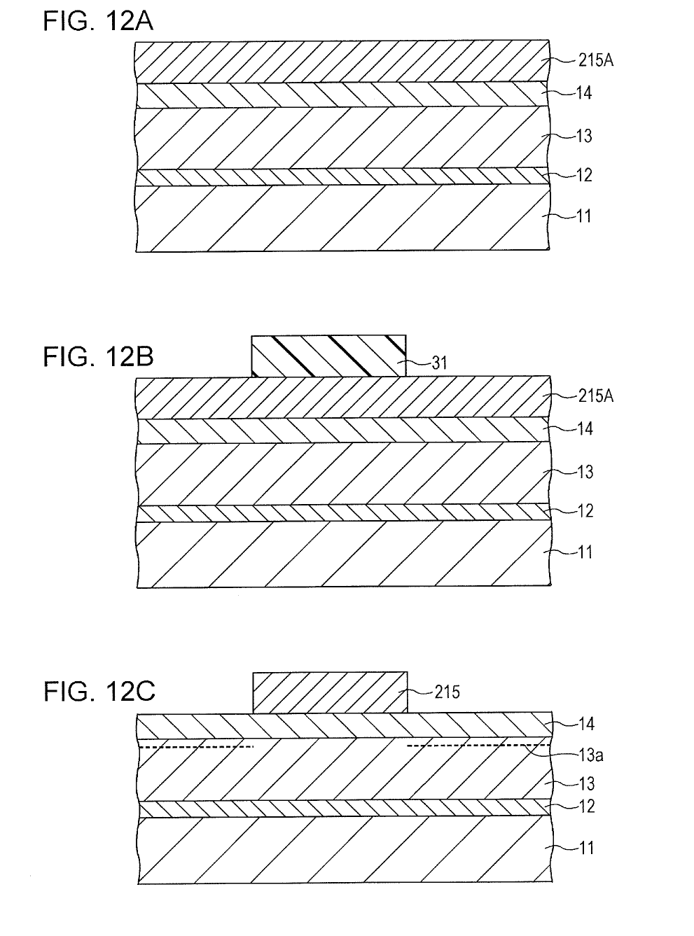

Next, a method of manufacturing the semiconductor device according to the third embodiment is described with reference to FIGS. 12A-12C, 13A-13C and 14.

First, as illustrated in FIG. 12A, nitride semiconductor layers of the buffer layer 12, the electron channel layer 13, the electron donor layer 14, and a p-GaN film 215A, from which the p-GaN layer 215 is to be formed, are formed on the substrate 11 by epitaxially growing the respective layers by a MOVPE method. In the present embodiment, the buffer layer 12 may be formed, for example, by first forming about 160 nm thickness of AlN buffer layer and then forming about 500 nm thickness of AlGaN buffer layer on the AlN buffer layer thus formed. The electron channel layer 13 that serves as the first semiconductor layer is formed of about 1 μm thickness of GaN. The electron donor layer 14 that serves as the second semiconductor layer is formed of about 20 nm thickness of AlGaN. The p-GaN film 215A, from which the p-GaN layer 215 that serves as the third semiconductor layer is formed, is formed so as to have about 100 nm thickness, and is doped with Mg as an impurity element. The p-GaN film 215A may further include In, Al, etc.

Next, as illustrated in FIG. 12B, a resist pattern 31 is formed on the p-GaN film 215A. Specifically, the resist pattern 31 is formed over a region where the p-GaN layer 215 is formed by coating photoresist over the p-GaN film 215A and then performing exposure and development processes using a photolithography apparatus.

Next, as illustrated in FIG. 12C, dry etching is performed using an RIE or the like to remove the p-GaN film 215A from an exposed area where no resist pattern 31 is formed, thereby forming the p-GaN layer 215. In the dry etching by the RIE or the like, a chlorine gas such as Cl₂, BCl₃, etc. may be used as an etching gas. After that, the resist pattern 31 is removed by organic solvent or the like.

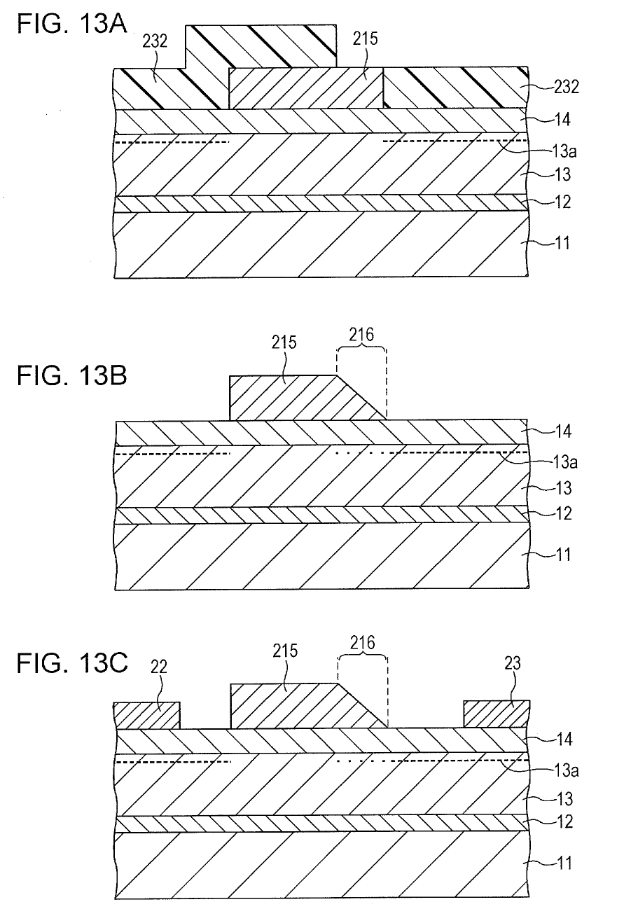

Next, as illustrated in FIG. 13A, a resist pattern 232 is formed on the p-GaN layer 215. The resist pattern 232 has an opening at a region where the jutting out region 216 is formed. Specifically, the resist pattern 232, which has the opening at the region where the jutting out region 216 is formed, is formed by coating photoresist over the p-GaN layer 215 and then performing exposure and development processes using the photolithography apparatus.

Next, as illustrated in FIG. 13B, dry etching is performed using an RIE or the like to remove part of the p-GaN layer 215 so as to form a slope-like shape at an exposed area where no resist pattern 232 is formed, thereby forming the jutting out region 216. Specifically, the jutting out region 216 having a slope-like shape is formed by obliquely injecting ions with respect to the substrate 11 during the dry etching. After that, the resist pattern 232 is removed by organic solvent or the like. Thus, the p-GaN layer 215 having the jutting out region 216 is formed on the predetermined area of the electron donor layer 14.

Next, as illustrated in FIG. 13C, the source electrode 22 and the drain electrode 23 are formed on the electron donor layer 14. Specifically, a resist pattern (not indicated in the figure) is formed by coating photoresist over the electron donor layer 14 and then performing exposure and development using the photolithography apparatus. The resist pattern has openings over regions where the source electrode 22 and the drain electrode 23 are to be formed. Subsequently, a Ti/Al multilayer metal film is deposited, and then dipped into organic solvent or the like to remove the Ti/Al multilayer metal film deposited on the resist pattern as well as the resist pattern itself by a lift-off method. Thus, the source electrode 22 and the drain electrode 23 made of Ti/Al are formed. In the Ti/Al multilayer metal film, a thickness of Ti is about 30 nm, and a thickness of Al is about 300 nm. Subsequently, rapid thermal annealing is performed at a temperature of about 600° C. to form ohmic contacts.

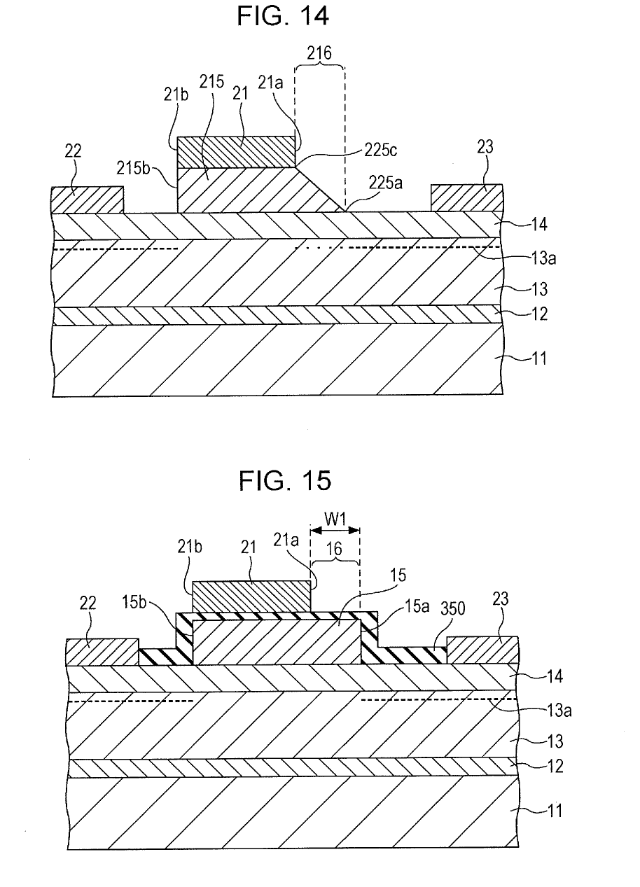

Next, as illustrated in FIG. 14, the gate electrode 21 is formed on the p-GaN layer 215 at a region except a region on which the jutting out region 216 is being formed. Specifically, a resist pattern (not indicated in the figure) is formed by coating photoresist over the p-GaN layer 215 and then performing exposure and development processes using the photolithography apparatus. The resist pattern has an opening over a region where the gate electrode 21 is to be formed. Subsequently, a Ni/Au multilayer metal film is deposited, and then dipped into organic solvent or the like to remove the Ni/Au multilayer metal film deposited on the resist pattern together with the resist pattern itself by the lift-off method. Thus, the gate electrode 21 made of Ni/Au is formed. In the Ni/Au multilayer metal film, a thickness of Ni is about 100 nm, and a thickness of Au is about 300 nm.

In the semiconductor device according to the present embodiment formed as described above, the jutting out region 216 of the p-GaN layer 215—namely a region jutting out toward the drain electrode 23 beyond the edge of the gate electrode in the p-GaN layer 215—has the width W3 of about 2 μm.

Except for the matters described above, the contents of the present embodiment are similar to those of the second embodiment.

### Fourth Embodiment

Semiconductor Device

A semiconductor device according to the fourth embodiment is described with reference to FIG. 15. As illustrated in FIG. 15, in the semiconductor device of the present embodiment, a buffer layer 12, an electron channel layer 13 that serves as a first semiconductor layer, and an electron donor layer 14 that serves as a second semiconductor layer are sequentially formed on a substrate 11. On a predetermined region of the electron donor layer 14, a p-GaN layer 15 that serves as a third semiconductor layer is formed, and an insulation film 350 that serves as a gate insulation film is formed on the p-GaN layer 15 thus formed. Furthermore, above the p-GaN layer 15, a gate electrode 21 is formed with having the insulation film 350 in between. Furthermore, a source electrode 22 and a drain electrode 23 are formed on the electron donor layer 14. In the present embodiment, the p-GaN layer 15 uses GaN doped with Mg, which is an impurity element that makes p-type.

In the present embodiment, the p-GaN layer 15 and the gate electrode 21 are formed in such a way that, on a side toward the drain electrode 23, an edge 15a of the p-GaN layer 15 is positioned closer to the drain electrode 23 than an edge 21a of the gate electrode 21. In the description of the present embodiment, it is assumed that an edge 15b of the p-GaN layer 15 and an edge 21b of the gate electrode 21 are aligned with each other on a side toward the source electrode 22. Alternatively, the edge 15b and the edge 21b are not aligned with each other.

Thus, in the p-GaN layer 15, a jutting out region 16 that juts out beyond the gate electrode 21 toward the drain electrode 23 is formed. In the jutting out region 16, a width toward the drain electrode 23‥namely a width from the edge 21a of the gate electrode 21 to the edge 15a of the p-GaN layer 15—will be referred to as W1.

In the semiconductor device according to the present embodiment, a gate leak current may be further reduced since the insulation film 350 that serves as the gate insulation film is formed.

Thus, as is the case of the first embodiment, in the present embodiment, 2DEG 13a having an electron depleted region directly below the p-GaN layer 15 is formed in the electron channel layer 13 near an interface of the electron channel layer 13 and the electron donor layer 14.

Semiconductor Device Manufacturing Method

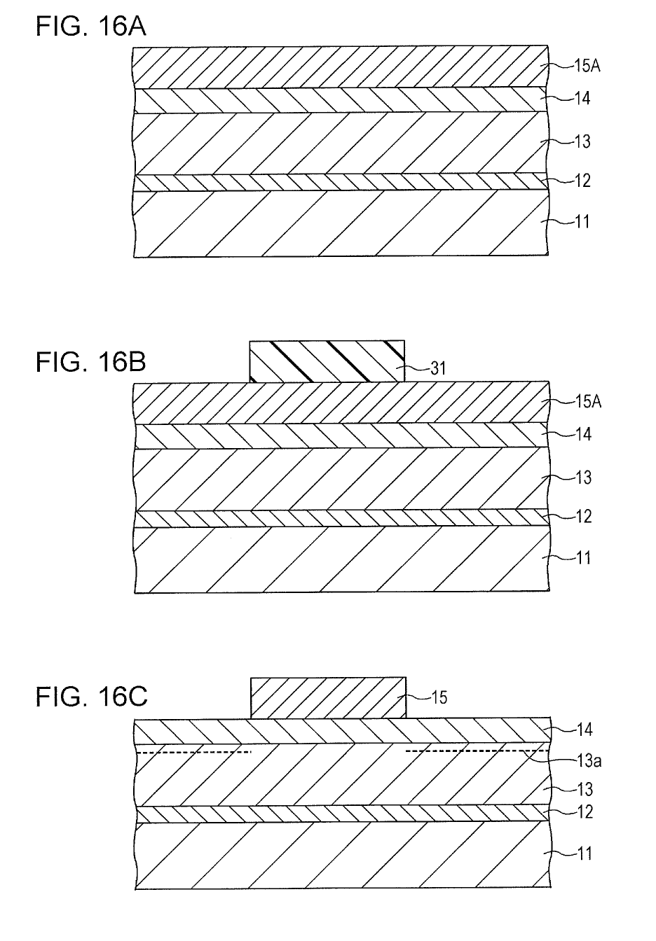

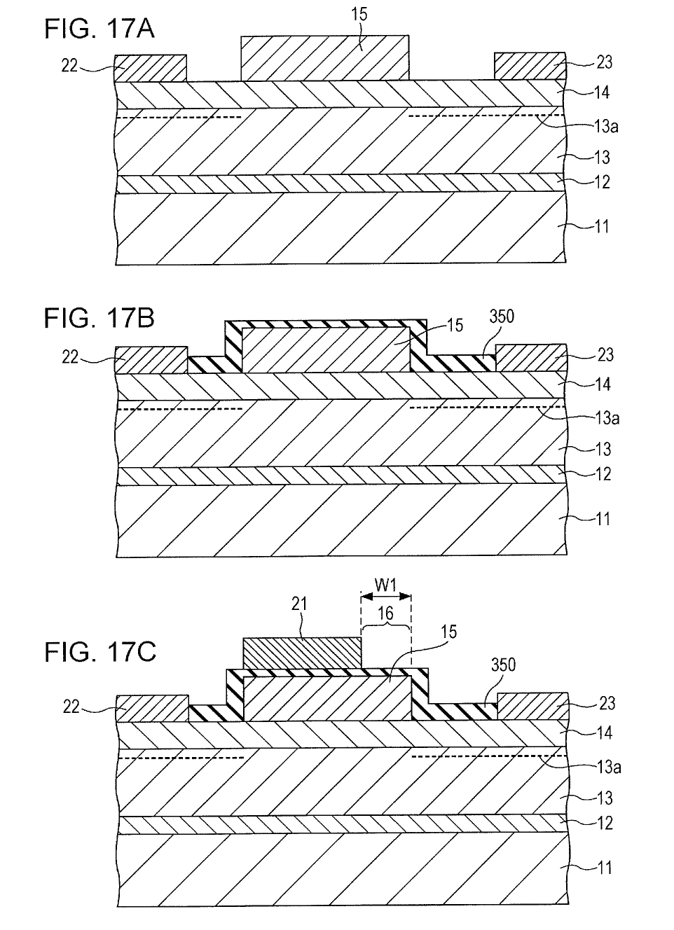

Next, a method of manufacturing the semiconductor device according to the fourth embodiment is described with reference to FIGS. 16A-16C and 17A-17C.

First, as illustrated in FIG. 16A, nitride semiconductor layers of the buffer layer 12, the electron channel layer 13, the electron donor layer 14, and a p-GaN film 15A, from which the p-GaN layer 15 is to be formed, are formed on the substrate 11 by epitaxially growing the respective layers by a MOVPE method. In the present embodiment, the buffer layer 12 may be formed, for example, by first forming about 160 nm thickness of AlN buffer layer and then forming about 500 nm thickness of AlGaN buffer layer on the AlN buffer layer thus formed. The electron channel layer 13 that serves as the first semiconductor layer is formed of about 1 μm thickness of GaN. The electron donor layer 14 that serves as the second semiconductor layer is formed of about 20 nm thickness of AlGaN. The p-GaN film 15A, from which the p-GaN layer 15 that serves as the third semiconductor layer is formed, is formed so as to have about 100 nm thickness, and is doped with Mg as an impurity element. The p-GaN layer 15 may further include In, Al, etc.

Next, as illustrated in FIG. 16B, a resist pattern 31 is formed on the p-GaN film 15A. Specifically, the resist pattern 31 is formed over a region where the p-GaN layer 15 is formed by coating photoresist over the p-GaN film 15A and then performing exposure and development processes using a photolithography apparatus.

Next, as illustrated in FIG. 16C, dry etching is performed using an RIE or the like to remove the p-GaN film 15A from an exposed area where no resist pattern 31 is formed, thereby forming the p-GaN layer 15. In this way, the p-GaN layer 15 may be formed over the predetermined area of the electron donor layer 14. In the dry etching by the RIE or the like, a chlorine gas such as Cl₂, BCl₃, etc. may be used as an etching gas. After that, the resist pattern 31 is removed by organic solvent or the like.

Next, as illustrated in FIG. 17A, the source electrode 22 and the drain electrode 23 are formed on the electron donor layer 14. Specifically, a resist pattern (not indicated in the figure) is formed by coating photoresist over the electron donor layer 14 and then performing exposure and development using the photolithography apparatus. The resist pattern has openings over regions where the source electrode 22 and the drain electrode 23 are to be formed. Subsequently, a Ti/Al multilayer metal film is deposited, and then dipped into organic solvent or the like to remove the Ti/Al multilayer metal film deposited on the resist pattern as well as the resist pattern itself by a lift-off method. Thus, the source electrode 22 and the drain electrode 23 made of Ti/Al are formed. In the Ti/Al multilayer metal film, a thickness of Ti is about 30 nm, and a thickness of Al is about 300 nm. Subsequently, rapid thermal annealing is performed at a temperature of about 600° C. to form ohmic contacts.

Next, as illustrated in FIG. 17B, the insulation film 350 that serves as the gate insulation film is formed on the p-GaN layer 15. Specifically, a process of atomic layer deposition (ALD) is performed to deposit an aluminum oxide film so as to have a thickness of about 10 nm.

Next, as illustrated in FIG. 17C, the gate electrode 21 is formed above the p-GaN layer 15 with having the insulation film 350 in between. The gate electrode 21 is formed such that the p-GaN layer 15 has the predetermined jutting out region 16. Specifically, a resist pattern (not indicated in the figure) is formed by coating photoresist over the insulation film 350 and then performing exposure and development processes using the photolithography apparatus. The resist pattern has an opening over a region where the gate electrode 21 is to be formed. Subsequently, a Ni/Au multilayer metal film is deposited, and then dipped into organic solvent or the like to remove the Ni/Au multilayer metal film deposited on the resist pattern together with the resist pattern itself by the lift-off method. Thus, the gate electrode 21 made of Ni/Au is formed. In the Ni/Au multilayer metal film, a thickness of Ni is about 100 nm, and a thickness of Au is about 300 nm. In the semiconductor device according to the present embodiment formed as described above, the width W1 of the jutting out region 16 on the p-GaN layer 15 is about 2 μm.

Except for the matters described above, the contents of the present embodiment are similar to those of the first embodiment.

### Fifth Embodiment

Next, the fifth embodiment is described. The present embodiment relates to a packaged semiconductor device, a power supply, and a high frequency amplifier.

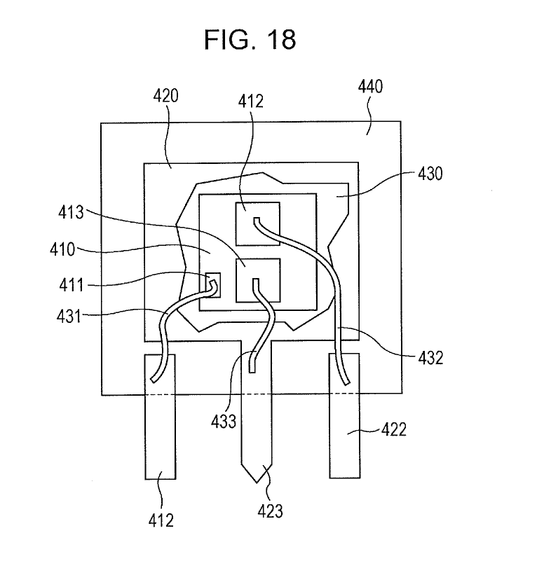

The packaged semiconductor device according to the present embodiment is formed by discretely packaging one of the semiconductor devices according to the first to fourth embodiments. Such a discretely packaged semiconductor device is described with reference to FIG. 18. Note that FIG. 18 schematically illustrates an inner structure of the discretely packaged semiconductor device, and an electrode arrangement, etc. may differ from what is indicated in the first to fourth embodiments.

First, semiconductor chips 410 that are GaN based semiconductor HEMTs are formed by cutting semiconductor devices manufactured according to one of the first to fourth embodiments using dicing or the like. The semiconductor chip 410 is fixed on a lead-frame 420 using a die attaching agent 430 such as solder, etc. The semiconductor chip 410 corresponds to one of the semiconductor devices according to the first to fourth embodiments.

Next, a gate electrode 411 is connected to a gate lead 421 by a bonding wire 431, a source electrode 412 is connected to a source lead 422 by a bonding wire 432, and a drain electrode 413 is connected to a drain lead 423 by a bonding wire 433. The bonding wires 431, 432, 433 are made of a metal material such as Al, etc. Furthermore, in the present embodiment, the gate electrode 411 is a gate electrode pad, which is connected to the gate electrode 21 of one of the semiconductor devices according to the first to fourth embodiments. The source electrode 412 is a source electrode pad, which is connected to the source electrode 22 of one of the semiconductor devices according to the first to fourth embodiments. The drain electrode 413 is a drain electrode pad, which is connected to the drain electrode 23 of one of the semiconductor devices according to the first to fourth embodiments.

Next, resin sealing is performed with molding resin 440 by a transfer molding method. Thus, the discretely packaged semiconductor device of GaN based semiconductor HEMT may be manufactured.

Next, a power supply and a high frequency amplifier according to the present embodiment are described. The power supply and the high frequency amplifier according to the present embodiment each use one of the semiconductor devices according to the first to fourth embodiments.

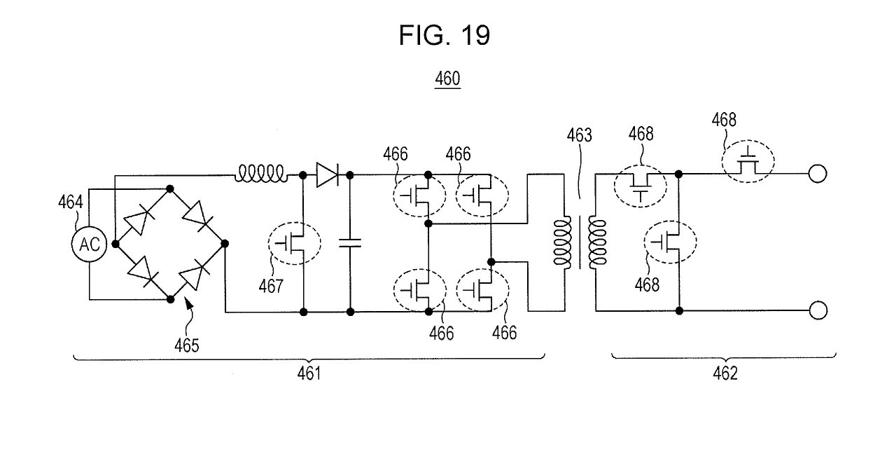

First, the power supply according to the present embodiment is described with reference to FIG. 19. A power supply 460 according to the present embodiment includes a high-voltage primary side circuit 461, a low-voltage secondary side circuit 462, and a transformer 463 that is provided between the primary side circuit 461 and the secondary side circuit 462. The primary side circuit 461 includes an AC power source 464, a so-called bridge rectifier circuit 465, a plurality of switching elements 466 (four in the example illustrated in FIG. 19), a single switching element 467, etc. The secondary side circuit 462 includes a plurality of switching elements 468 (three in the example illustrated in FIG. 19). In the example illustrated in FIG. 19, the semiconductor devices according to the first to fourth embodiments are used as the switching elements 466, 467 of the primary side circuit 461. It is preferable that the switching elements 466, 467 of the primary side circuit 461 are normally-off semiconductor devices. The switching elements 468 used in the secondary side circuit 462 are typical metal insulator semiconductor field effect transistors (MISFETs) that are formed from silicon.

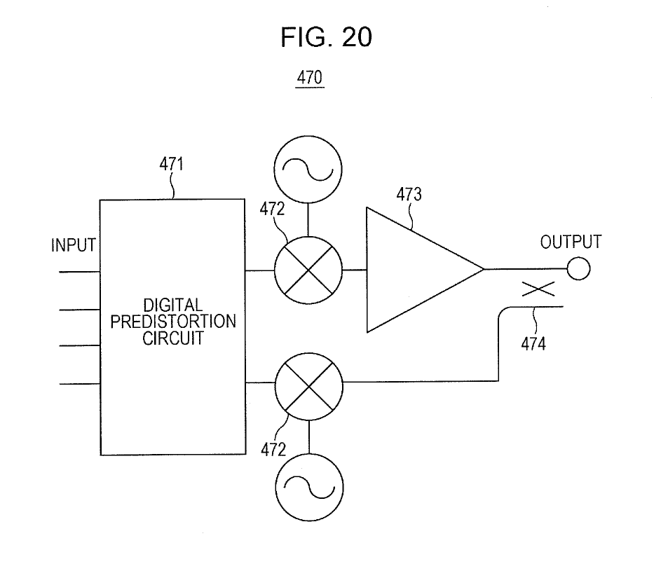

Next, the high frequency amplifier according to the present embodiment is described with reference to FIG. 20. A high frequency amplifier 470 according to the present embodiment may be employed as, for example, a power amplifier for a mobile phone base station. The high frequency amplifier 470 includes a digital predistortion circuit 471, mixers 472, a power amplifier 473, and a directional coupler 474. The digital predistortion circuit 471 compensates nonlinear distortions of an input signal. The mixer 472 mixes an AC signal and the input signal in which the nonlinear distortion is compensated. The power amplifier 473 amplifies the input signal mixed with the AC signal. In an example illustrated in FIG. 20, the power amplifier 473 includes one of the semiconductor devices according to the first to fourth embodiments. The directional coupler 474 monitors the input signal and/or an output signal, or performs other processes. The circuit illustrated in FIG. 20 may, for example, by turning a switch, mix the output signal and the AC signal by the mixer 472 and then send a mixed signal to the digital predistortion circuit 471.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a first semiconductor layer formed on a substrate;
a second semiconductor layer formed on the first semiconductor layer;
a third semiconductor layer formed on the second semiconductor layer;
a gate electrode formed on the third semiconductor layer; and
a source electrode and a drain electrode formed in contact with the second semiconductor layer,
wherein a semiconductor material of the third semiconductor layer is doped with a p-type impurity element; and
the third semiconductor layer has a jutting out region that juts out beyond an edge of the gate electrode toward a side where the drain electrode is provided.

2. The semiconductor device according to claim 1,
wherein the jutting out region has a width equal to or larger than 100 nm in a direction toward the drain electrode; and
the width is equal to or less than 0.8×D, where D is a distance between the gate electrode and the drain electrode.

3. The semiconductor device according to claim 1,
wherein the third semiconductor layer is thinner in the jutting out region than a region above which the gate electrode is formed.

4. The semiconductor device according to claim 3,
wherein a thickness of the jutting out region is equal to or larger than 10 nm.

5. The semiconductor device according to claim 1,
wherein a thickness of the third semiconductor layer in the jutting out region gradually decreases as a distance from an edge of a region where the gate electrode is formed increases toward a side where the drain electrode is formed.

6. The semiconductor device according to claim 1,
wherein an insulation film is provided between the third semiconductor layer and the gate electrode.

7. The semiconductor device according to claim 6,
wherein the insulation film is formed from aluminum oxide.

8. The semiconductor device according to claim 1,
wherein the p-type impurity element is Mg.

9. The semiconductor device according to claim 1,
wherein the first semiconductor layer, the second semiconductor layer, and the third semiconductor layer are formed from respective nitride semiconductors.

10. The semiconductor device according to claim 1,
wherein the semiconductor material of the third semiconductor layer is a material including GaN.

11. The semiconductor device according to claim 1,
wherein the first semiconductor layer is formed from a material including GaN.

12. The semiconductor device according to claim 1,
wherein the second semiconductor layer is formed from a material including AlGaN.

13. A power supply comprising the semiconductor device,
wherein a semiconductor device includes:
a first semiconductor layer formed on a substrate;
a second semiconductor layer formed on the first semiconductor layer;
a third semiconductor layer formed on the second semiconductor layer;
a gate electrode formed on the third semiconductor layer; and
a source electrode and a drain electrode formed in contact with the second semiconductor layer,
wherein a semiconductor material of the third semiconductor layer is doped with a p-type impurity element; and
the third semiconductor layer has a jutting out region that juts out beyond an edge of the gate electrode toward a side where the drain electrode is provided.

14. An amplifier comprising the semiconductor device,
wherein a semiconductor device includes:
a first semiconductor layer formed on a substrate;
a second semiconductor layer formed on the first semiconductor layer;
a third semiconductor layer formed on the second semiconductor layer;
a gate electrode formed on the third semiconductor layer; and
a source electrode and a drain electrode formed in contact with the second semiconductor layer,
wherein a semiconductor material of the third semiconductor layer is doped with a p-type impurity element; and
the third semiconductor layer has a jutting out region that juts out beyond an edge of the gate electrode toward a side where the drain electrode is provided.

15. A method of manufacturing a semiconductor device, comprising:
sequentially depositing a first semiconductor layer and a second semiconductor layer on a substrate;
forming a third semiconductor layer on the second semiconductor layer at a predetermined region, the third semiconductor layer including a p-type impurity element;
forming a source electrode and a drain electrode in contact with the second semiconductor layer; and
forming a gate electrode on the third semiconductor layer;
wherein an edge of the third semiconductor layer on a drain electrode side is formed closer to the drain electrode than an edge of the gate electrode on the drain electrode side.

16. The method of manufacturing a semiconductor device according to claim 15,
wherein the forming of the third semiconductor layer includes: depositing a film including the p-type impurity element on the second semiconductor layer; and
subsequently removing the film including the p-type impurity element from a region except the predetermined region.

17. The method of manufacturing a semiconductor device according to claim 15,
wherein, in the third semiconductor layer, a region where the gate electrode is not formed on the drain electrode side is a jutting out region,
the method further comprising, after the forming of the third semiconductor layer, thinning a thickness of the third semiconductor layer in the jutting out region compared to a thickness of a region directly below the gate electrode.

18. The method of manufacturing a semiconductor device according to claim 15,
wherein, a region of the third semiconductor layer on the drain electrode side, where the gate electrode is not formed, is a jutting out region; and
after the forming of the third semiconductor layer, a portion of the third semiconductor layer is removed by dry etching in which ions are obliquely injected with respect to the substrate in such a way that a thickness of the third semiconductor layer gradually decreases as a position moves from a side where the gate electrode is provided to a side where the drain electrode is provided.

19. The method of manufacturing a semiconductor device according to claim 15, further comprising:
forming an insulation film on the third semiconductor layer;
wherein the gate electrode is formed above the third semiconductor layer with having the insulation film in between.

20. The method of manufacturing a semiconductor device according to claim 15,
wherein the p-type impurity element is Mg.
